(19) United States
(12) Patent Application Publication
(10) Pub. No.: US 2010/0301418 A1
(43) Pub. Date: Dec. 2, 2010

(54) ELECTROSTATIC DISCHARGE PROTECTION DEVICE

(75) Inventor: Kil Ho Kim, Icheon-si (KR)

Correspondence Address: SCHMEISER, OLSEN & WATTS, 22 CENTURY HILL DRIVE, SUITE 302, LATHAM, NY, 12110, US

(73) Assignee: BauaBTech

(21) Appl. No.: 12/787,462

(22) Filed: May 26, 2010

(30) Foreign Application Priority Data
May 28, 2009 (KR) 10-2009-0046928

(51) Int. Cl. H01L 27/06

(52) U.S. Cl. 257/360; 257/E27.016

(57) ABSTRACT

Disclosed is an electrostatic discharge protection device that overcomes problems of an LVTNR device by serially connecting a diode to the LVTNR device and coupling a gate of a MOSFET structure thereto. The electrostatic discharge protection device of the present invention includes a diode comprising N well/P⁺ diffusion regions; a resistor connected in parallel to the diode; a MOS transistor having a drain connected to the diode and the resistor and constituting a cathode along with a source and a gate; and at least one diode connected in series to the cathode.

### BACKGROUND OF THE INVENTION

1. Field of the Invention

The present invention relates to semiconductor devices and, more particularly, to an electrostatic discharge protection device that overcomes problems of a low voltage triggering N-type rectifier (LVTNR) device by serially connecting a diode to the LVTNR device and coupling a gate of a MOSFET structure thereto.

2. Description of the Related Art

In general, semiconductor devices include an electrostatic discharge (ESD) protection circuit between a pad and a core circuit to protect the core circuit. The electrostatic discharge protection circuit prevents chip failure that is likely to occur when static electricity caused by contact between an external pin of a microchip and a charged human body or a charged machine is discharged to a core circuit or when accumulated static electricity flows to the core circuit. In fabrication of microchips, it is an essential technique of chip design to design a circuit for protecting a microchip from ESD stress. A device used for designing the protection circuit for the ESD stress is referred to as an ESD protection device, which must satisfy some fundamental requirements. These requirements will be briefly described with reference to FIG. 1.

FIG. 1 is a graphical representation depicting fundamental requirements for an electrostatic discharge protection device.

First, the ESD protection device has to prevent current flow therethrough upon application of a voltage less than or equal to an operation voltage Vop to the ESD protection device during normal operation of the microchip adopting the ESD protection device. To this end, the avalanche breakdown voltage Vav and the triggering voltage Vtr of the ESD protection device must be greater than the operation voltage of the microchip during normal operation of the microchip (Vav, Vtr>Vop).

Second, the ESD protection device must be able to provide sufficient protection to a core circuit in the microchip when the microchip is subjected to electrostatic discharge stress. In other words, when an ESD current flows to the microchip, it must be discharged to the outside through the ESD protection device before flowing to the core circuit. To this end, the triggering voltage Vtr of the ESD protection device must be sufficiently lower than the core circuit breakdown voltage Vccb of the microchip under the circumstance that ESD stress is generated in the microchip (Vtr<Vccb).

Third, an efficient ESD protection device generally exhibits a resistance snapback characteristic wherein on-state resistance of the ESD protection device is reduced after the device is triggered. Such a resistance snapback characteristic is exhibited as a voltage snapback phenomenon wherein corresponding voltage is lowered regardless of an increase in current flowing through the ESD protection device. Here, if the snapback phenomenon becomes too strong, the ESD protection device suffers a latch-up phenomenon allowing excess current to flow through the ESD protection device, thereby causing thermal breakdown of the microchip, even in the case where the microchip is normally operated. The ESD protection device must be prevented from abnormal operation resulting from the latch-up phenomenon. To this end, the snapback holding voltage Vh of the ESD protection device must be greater than the operation voltage of the microchip by a sufficient safety margin Δ V (Vh>Vop+ΔV). Otherwise, the triggering current Itr must be sufficiently greater than a certain value (Itr>˜100 mA).

Fourth, the ESD protection device generally adopts a multi-finger structure wherein devices having a constant size are arranged in parallel to each other for efficient use of a layout area. When adopting such a multi-finger structure, it is necessary for the respective fingers of the ESD protection device to operate uniformly. In other words, the respective fingers of the ESD protection device cooperate to discharge an injected electrostatic discharge current to the outside. To this end, other fingers must also be triggered to cooperatively discharge the ESD current before a certain finger is triggered and suffers thermal breakdown. To satisfy this requirement, the thermal breakdown voltage Vtb of the ESD protection device must be greater than or at least similar to the triggering voltage (Vtr≦Vtb) thereof.

Fifth, the ESD protection device must ensure sufficient immunity to electrostatic discharge current while having as small a size as possible. In other words, the electrostatic discharge protection device must endure a large amount of electrostatic discharge current sufficiently well while requiring a small layout area for installation of the ESD protection device on a chip.

There are various kinds of electrostatic discharge protection device used for protection of a microchip from the ESD stress. Among these ESD protection devices, a gate grounded N-type MOSFET (GGNMOS) electrostatic discharge protection device is most commonly used in practice. Structure and operation of the GGNMOS device will be described hereinafter.

FIG. 2A is a circuit diagram of a GGNMOS device, FIG. 2B is a sectional view illustrating a fundamental structure of the GGNMOS device, and FIG. 2C is a graphical representation depicting electrical characteristics of the GGNMOS device.

Referring to FIGS. 2A and 2B, a deep N-well (DNW) 100 as an N-type region is disposed to electrically separate a GGNMOS device from a P-type silicon substrate (not shown), and a P-well (PW) 110 as a P-type region is disposed in the deep N-well 100. A pick-up P⁺ region 120, a source region 122 and a drain region 124 are disposed in the PW 110, and an N⁺ region 126 is disposed for DNW pick-up to electrically connect a portion of the DNW region 100 excluding the PW region in the DNW region 100. A polysilicon gate 130 is disposed between the source region 122 and the drain region 124. The gate 130, the source region 122 and the pick-up region 120 are combined to constitute a cathode, and the drain region 124 and the N⁺ region 126 for DNW pick-up are combined to constitute an anode.

In this structure, when a ground voltage is applied to the cathode and a positive electrostatic discharge current is applied to the anode, an LNPN bipolar transistor is formed between the drain region 124, the P-well 110 and the source region 122 in the GGNMOS device to process the electrostatic discharge current.

During normal operation of a microchip, the avalanche voltage Vav and the triggering voltage Vtr of the GGNMOS device are greater than the operation voltage Vop of the microchip. The GGNMOS device is an ESD protection device based on the MOSFET structure and a core circuit of the microchip is also based on the MOSFET structure. Thus, when electrostatic discharge stress is generated in the microchip, the triggering voltage of the GGNMOS device is substantially the same as the triggering voltage of the core circuit to be protected by the GGNMOS device. The core circuit of the microchip is very vulnerable to electrostatic discharge current. In other words, in the event where slight electrostatic discharge current flows to the core circuit due to application of a triggering voltage thereto, the core circuit is highly likely to undergo immediate thermal breakdown. Therefore, the triggering voltage Vtr of the core circuit is the same as the core circuit breakdown voltage thereof. Conclusively, the triggering voltage Vtr of the GGNMOS device is substantially the same as the core circuit breakdown voltage Vccb of the core circuit. Accordingly, the GGNMOS device has difficulty in providing fundamental prevention of the electrostatic discharge current injected in the microchip from flowing into the core circuit and causing breakdown of the core circuit.

Further, the snapback holding voltage Vh of the GGNMOS device is sufficiently greater than the operation voltage Vop of the microchip. Therefore, when the microchip is normally operated, there is no problem relating to the latch-up phenomenon due to the GGNMOS device.

The thermal breakdown voltage Vtb of the GGNMOS device is substantially similar to the triggering voltage Vtr thereof. Thus, when the GGNMOS device adopts the multi-finger structure, the respective fingers of the GGNMOS device perform relatively uniform operation.

Generally, the GGNMOS device may be manufactured to have immunity to a large amount of electrostatic discharge current by increasing the size of the device, that is, an overall diffusion width of the device. In this regard, however, there is a problem in that the GGNMOS device must be excessively enlarged in order to dissipate a sufficiently large amount of electrostatic discharge current. Generally, the GGNMOS device has a current immunity level of only 5˜10 mM/μm per unit size of the GGNMOS device. Thus, it is necessary to maintain the overall diffusion width in the range of about 200˜400 μm in order to correspond to the Industrial Standard 2A for electrostatic discharge current. In addition, the drain of the MOSFET must have a predetermined size or more for the GGNMOS device to maintain the optimal immunity to the electrostatic discharge current. For the same reason, the GGNMOS device adopted as the ESD protection device for the microchip causes a burden of increasing the overall size of the microchip.

Conclusively, the GGNMOS device satisfies some of the requirements for the electrostatic discharge protection device, and thus, is most commonly used as the ESD protection device in the art. As described previously, however, the GGNMOS device has a problem in that it does not provide sufficient protection to the core circuit of the microchip. Further, in order to handle the large amount of electrostatic discharge current, the GGNMOS device is excessively enlarged, causing the burden of increasing the overall size of the microchip. Therefore, in order to solve such problems, there is a need for development of a new electrostatic discharge protection device.

FIGS. 3A to 3C illustrate an example of another conventional ESD protection device, in which FIG. 3A is a circuit diagram of a low voltage triggering N-type rectifier (LVTNR) device, FIG. 3B is a sectional view of the LVTNR device, and FIG. 3C is a graphical representation depicting electrical characteristics of the LVTNR device.

Referring to FIGS. 3A and 3B, a deep N-well (DNW) 300 as an N-type region is disposed to electrically separate an LVTNR device from a P-type silicon substrate (not shown), and a P-well (PW) 310 as a P-type region and an N-well (NW) 320 as an N-type region are disposed in the DNW region 300. The PW region and the NW region adjoin each other at an interface therebetween.

A cathode P⁺ region 311 and a cathode N⁺ region 312 are disposed in the PW region 310, and an anode P⁺ region 321 and an anode N⁺ region 322 are disposed in the NW region 320. A drain region 330 is disposed over both well regions at an interface between the PW region 310 and the NW region 320. A poly-silicon gate 340 is disposed between the cathode N⁺ region 312 and the drain region 330. The cathode P⁺ region 311 and the cathode N⁺ region 312 are combined with the gate 340 to constitute a cathode, and the P⁺ region 321 and the N⁺ region 322 are combined to constitute an anode.

Although such an LVTNR device exhibits excellent efficiency of a layout area, it has a limit due to insufficient protection of the core circuit of the microchip. Further, the LVTNR device has difficulty being adopted as the ESD protection device due to the latch-up phenomenon and a non-linearity of current immunity in the multi-finger structure. Therefore, it is advisable to provide methods for solving such problems in order to adopt the LVTNR device as the ESD protection device.

### SUMMARY OF THE INVENTION

The present invention is conceived to solve the above problems of the state of the to art, and an aspect of the invention is to provide a new electrostatic discharge protection device that overcomes problems of an LVTNR device by serially connecting a diode to the LVTNR device and coupling a gate of a MOSFET structure thereto.

In accordance with an aspect of the present invention, an electrostatic discharge protection device includes a diode comprising N well/P⁺ diffusion regions; a resistor connected in parallel to the diode; a MOS transistor having a drain connected to the diode and the resistor and constituting a cathode along with a source and a gate; and at least one diode connected in series to the cathode.

The ESD protection device may include a deep-N well region formed in a predetermined region on a semiconductor substrate and a P well region and an N well region formed adjacent to each other in the deep-N well region, wherein the MOS transistor may be formed in the P well region and the resistor may include an impurity region formed in the N well region.

The diode connected to the cathode electrode may include a P well region for the diode formed a predetermined distance from a side of a well region where the MOS transistor is disposed, and an inner N⁺ impurity region and a P⁺ impurity region for diode pick-up formed in the P well region for the diode.

The P well region for the diode may be electrically separated from the MOS transistor by an N-type well disposed between the P well region for the diode and the well region where the MOS transistor is disposed.

The inner N⁺ impurity region for the diode may be connected to the cathode.

The ESD protection device may further include a capacitor connected between an anode of the diode and the gate of the MOS transistor, and a resistor connected between the anode of the diode connected to the cathode and the gate of the MOS transistor.

In accordance with another aspect of the invention, an ESD protection device includes a diode comprising N well/P⁺ diffusion regions; a MOS transistor having a drain connected to the diode and constituting a cathode along with a source and a gate; and at least one diode connected in series to the cathode.

The ESD protection device may include a deep-N well region formed in a predetermined region on a semiconductor substrate and a P well region and an N well to region formed adjacent to each other in the deep-N well region, wherein the MOS transistor may be formed in the P well region.

The ESD protection device may further include a P well region for a capacitor disposed adjacent to the N well region, and the capacitor may be coupled to the gate of the MOS transistor.

The diode connected to the cathode electrode may include a P well region for the diode formed a predetermined distance from a side of a MOS transistor, and an inner N⁺ impurity region and a P⁺ impurity region for picking-up the diode formed in the P well region for the diode.

The P well region for the diode may be electrically separated from the MOS transistor by an N-type well disposed between the P well region and the MOS transistor.

The inner N⁺ impurity region for the diode may be connected to the cathode electrode.

The ESD protection device may further include a capacitor connected between an anode of the diode and the gate of the MOS transistor, and a resistor connected between the anode of the diode connected to the cathode electrode and the gate of the MOS transistor, and the capacitor may be coupled to the gate of the MOS transistor.

In accordance with a further aspect of the invention, an electrostatic discharge protection device includes: a semiconductor substrate; a deep-N well region formed in a predetermined region on the semiconductor substrate; a P well region and an N well region formed adjacent to each other in the deep-N well region; a MOS transistor formed in the P well region; and an anode P⁺ impurity region for an anode formed in the N well region, wherein the anode P⁺ impurity region is connected to an anode.

The ESD protection device may further include a P well region for a capacitor disposed adjacent to the N well region, and the capacitor may be coupled to a gate of the MOS transistor.

The ESD protection device may further include at least one diode connected in series to a cathode of the MOS transistor.

### BRIEF DESCRIPTION OF THE DRAWINGS

The above and other aspects, features and advantages of the invention will become apparent from the following detailed description in conjunction with the accompanying drawings, in which:

FIG. 1 is a graphical representation depicting fundamental requirements for an electrostatic discharge protection device;

FIG. 2A is a circuit diagram of a GGNMOS device, FIG. 2B is a sectional view illustrating a fundamental structure of the GGNMOS device, and FIG. 2C is a graphical representation depicting electrical characteristics of the GGNMOS device;

FIG. 3A is a circuit diagram of a low voltage triggering N-type rectifier (LVTNR) device, FIG. 3B is a sectional view of the LVTNR device, and FIG. 3C is a graphical representation depicting electrical characteristics of the LVTNR device;

FIGS. 4A and 4B are a circuit diagram and a sectional view of an electrostatic discharge protection device in accordance with a first embodiment of the present invention;

FIGS. 5A and 5B are a circuit diagram and a sectional view of an electrostatic discharge protection device in accordance with a second embodiment of the present invention;

FIG. 6 is a graphical representation depicting electrical characteristics upon application of electrostatic discharge current between a cathode and an anode of the SDAGGNR device in accordance with the first and second embodiments;

FIGS. 7A and 7B are a circuit diagram and a sectional view of an electrostatic discharge protection device in accordance with a third embodiment of the present invention;

FIGS. 8A and 8B are a circuit diagram and a sectional view of an electrostatic discharge protection device in accordance with a fourth embodiment of the present invention;

FIGS. 9A and 9B are graphical representations depicting electrical characteristics upon application of electrostatic discharge current between a cathode and an anode of the SDAGCNR device in accordance with the fourth and fifth embodiments;

FIGS. 10A and 10B are a circuit diagram and a sectional view of an electrostatic discharge protection device in accordance with a fifth embodiment of the present invention;

FIGS. 11A and 11B are a circuit diagram and a sectional view of an electrostatic discharge protection device in accordance with a sixth embodiment of the present invention;

FIGS. 12A and 12B are a circuit diagram and a sectional view of an electrostatic discharge protection device in accordance with a seventh embodiment of the present invention;

FIGS. 13A and 13B are a circuit diagram and a sectional view of an electrostatic discharge protection device in accordance with an eighth embodiment of the present invention;

FIGS. 14A and 14B are a circuit diagram and a sectional view of an electrostatic discharge protection device in accordance with a ninth embodiment of the present invention;

FIGS. 15A and 15B are a circuit diagram and a sectional view of an electrostatic discharge protection device in accordance with a tenth embodiment of the present invention;

FIGS. 16A and 16B are a circuit diagram and a sectional view of an electrostatic discharge protection device in accordance with an eleventh embodiment of the present invention;

FIGS. 17A and 17B are a circuit diagram and a sectional view of an electrostatic discharge protection device in accordance with a twelfth embodiment of the present invention;

FIGS. 18A and 18B are a circuit diagram and a sectional view of an electrostatic discharge protection device in accordance with a thirteenth embodiment of the present invention; and

FIGS. 19A and 19B are a circuit diagram and a sectional view of an electrostatic discharge protection device in accordance with a fourteenth embodiment of the present invention.

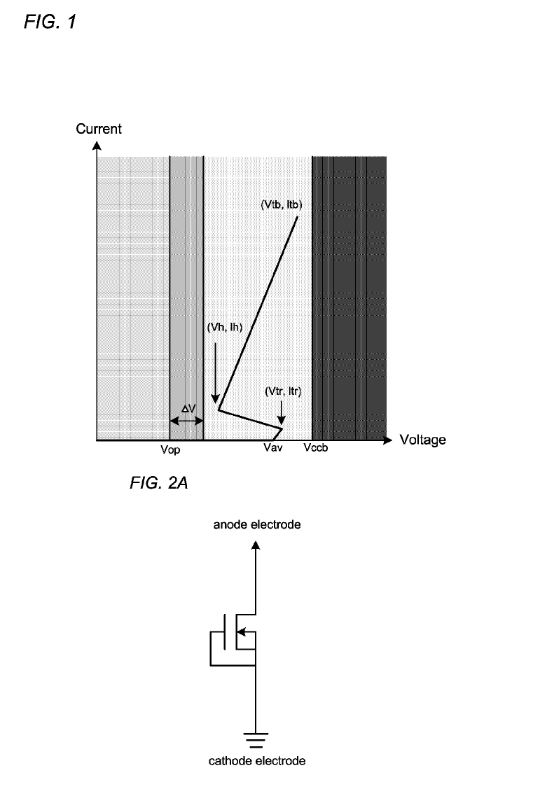

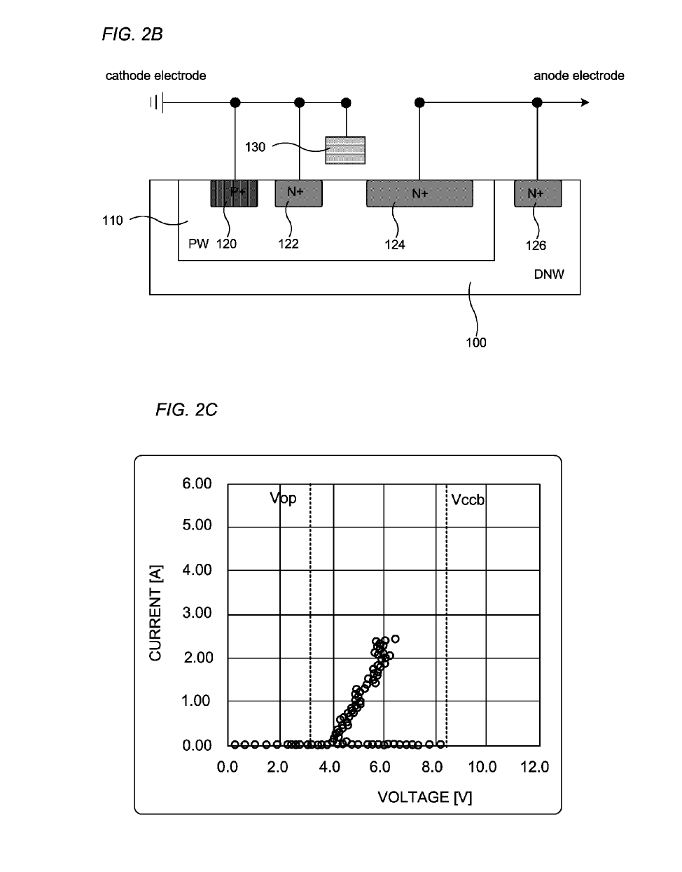

### DETAILED DESCRIPTION OF THE EMBODIMENTS

Embodiments of the invention will now be described in detail with reference to the accompanying drawings. It should be noted that the drawings are not to precise scale and may be exaggerated in thickness of lines or sizes of components for descriptive convenience and clarity only. Furthermore, the terms as used herein are defined by taking functions of the invention into account and can be changed according to the custom or intention of users or operators or according to the judicial precedents. Therefore, definition of the terms should be made according to the overall disclosure set forth herein.

The invention proposes a new electrostatic discharge protection device that solves problems of a conventional ESD protection device, for example an LVTNR device, by serially connecting a diode to the LVTNR device and coupling a gate of a MOSFET structure thereto. The ESD protection device according to the invention is a serial diode added N-type rectifier (SDANR) device wherein a diode is connected in series to an existing LVTNR device.

FIGS. 4A and 4B are a circuit diagram and a sectional view of an ESD protection device in accordance with a first embodiment of the invention, wherein a single N⁺ region/P well diode is connected in series to an LVTNR device.

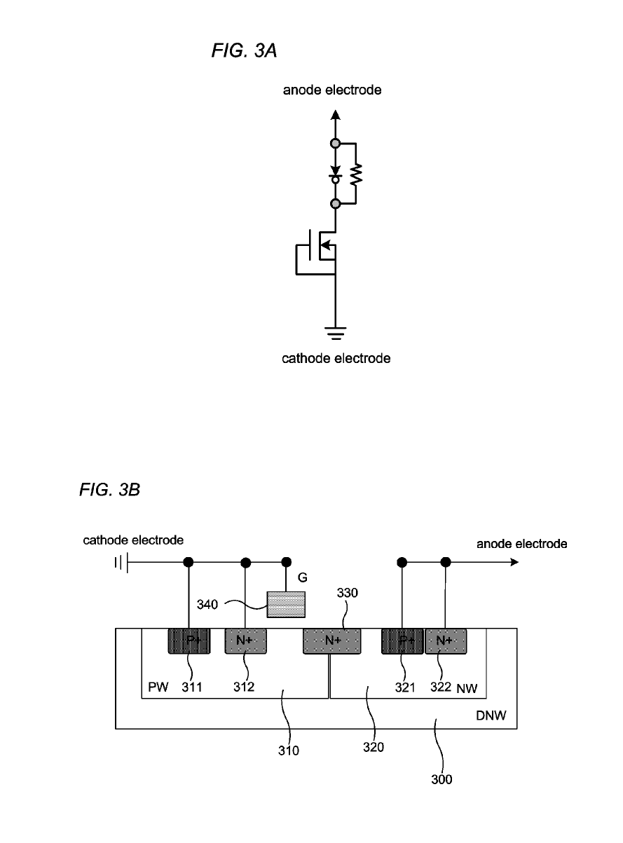

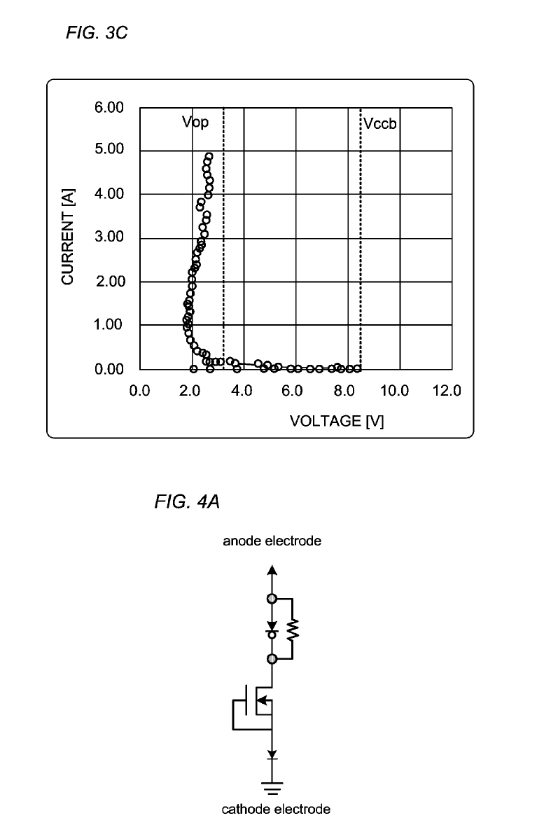

In the ESD protection device of this embodiment, a P well (PW2) 430 for a diode is additionally disposed near a P well (PW1) 410 for a MOSFET in the LVTNR device which includes the P well (PW1) 410 for the MOSFET and an anode N well (NW) 420 in a deep-N well (DNW) 400 formed in a predetermined region of a semiconductor substrate (not shown). An N well (NW) 440 is interposed between the two P wells 410, 430 to separate the P wells 410, 430 from each other. An N⁺ region 431 for internal diffusion of the diode and a P⁺ region 432 for diode pick-up are disposed inside the P well (PW) 430 for forming the diode. A cathode P⁺ region 411 and a cathode N⁺ region 412 are connected to a gate 450 and extend to be connected to the P⁺ region 432 for diode pick-up, and the N⁺ region 431 in the diode finally becomes a cathode. An anode P⁺ region 421 and an anode N⁺ region 422 of the LVTNR device are combined to constitute an anode. The structure of the LVTNR device disposed at the right side of FIG. 4B is the same as that shown in FIG. 3B and a detailed description thereof is thus omitted herein.

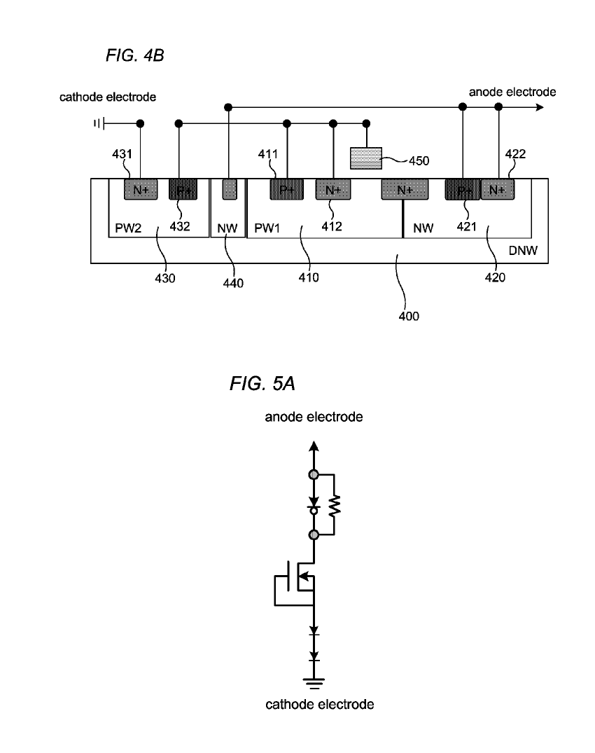

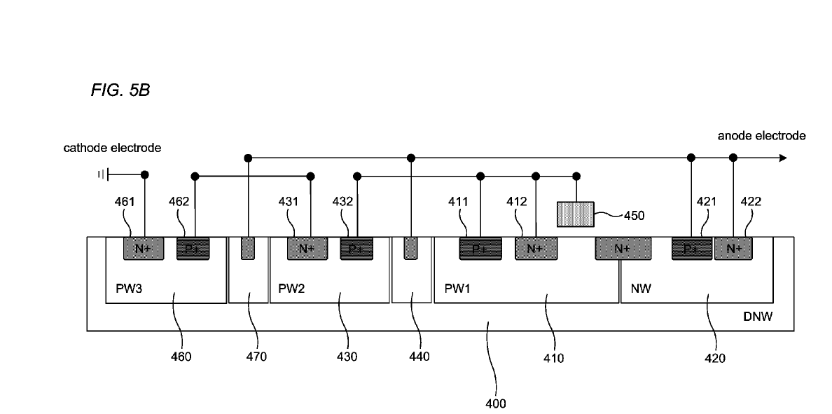

FIGS. 5A and 5B are a circuit diagram and a sectional view of an ESD protection device in accordance with a second embodiment of the invention, wherein two N⁺ region/P well diodes D1, D2 are connected in series to an LVTNR device.

Similar to the embodiment shown in FIGS. 4A and 4B, in the electrostatic discharge protection device of this embodiment, P wells 430, 460 for forming diodes are formed near a P well (PW1) 410 for a MOSFET in the LVTNR device which includes the P well (PW1) 410 for the MOSFET and an anode N well (NW) 420 in a deep-N well (DNW) 400. N wells (NW) 440, 470 are interposed between the respective P wells 410, 430, 460 to separate the P wells 410, 430, 460 from one another. N⁺ regions 431, 461 for internal diffusion of the diode and P⁺ regions 432, 462 for diode pick-up are disposed in the P wells 430, 460 for the diodes, respectively. The N⁺ region 431 connected to a distal end becomes a cathode, and an anode P⁺ region 421 and an anode N⁺ region 422 of the LVTNR device are combined to constitute an anode.

In each of the ESD protection device of the first and second embodiment, the gate 450 of the MOSFET structure is connected to ground only by forward behavior of the diode when coping with electrostatic discharge current. Thus, the devices according to the first and second embodiments may be referred to as a serial diode added gate grounded N-type rectifier (SDAGGNR) device.

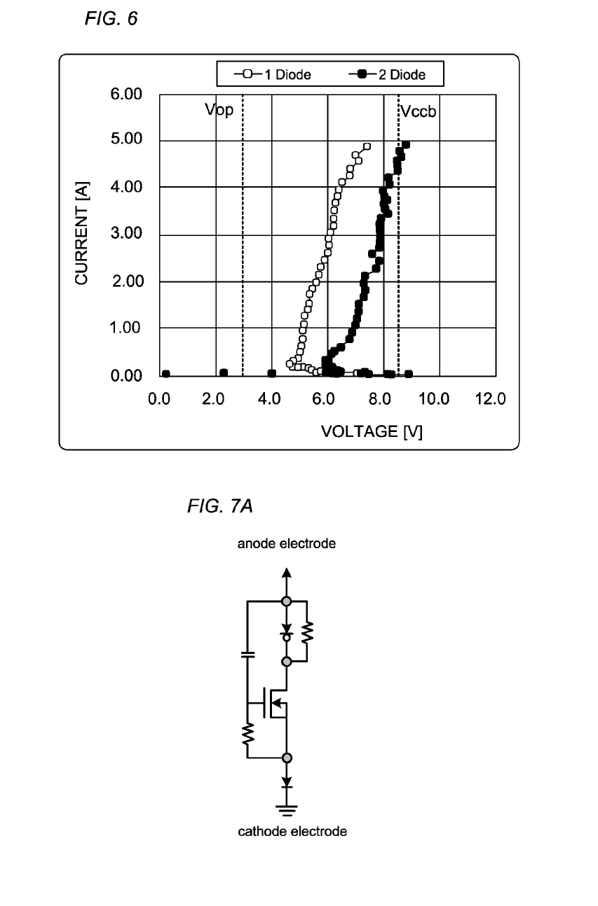

In such an SDAGGNR device, when a ground voltage and a positive voltage are applied to the cathode and anode, respectively, and electrostatic discharge current is applied between these two electrodes, the SDAGGNR device copes with the electrostatic discharge current by allowing diode forward operation to be performed simultaneously with rectifier operation of the LVTNR device. The rectifier operation of the LVTNR device exhibits a strong snap-back characteristic, as shown in FIG. 3C, whereas the diode forward operation exhibits an electrical characteristic wherein voltage increases in proportion to the amount of current passing therethrough without any strong snap-back characteristic. Thus, the electrical characteristics of the SDAGGNR device resulting from a combination of the rectifier operation of the LVTNR device and the diode forward operation of the SDAGGNR device are demonstrated with increased values of overall to characteristic voltages, such as avalanche voltage Vav, triggering voltage Vtr, snapback holding voltage Vh, thermal breakdown voltage Vtb, and the like, as shown in FIG. 6. Generally, as the number of added diodes increases, the respective characteristic voltage values increase. In other words, it is possible to optimize these characteristic voltage values by properly adjusting the size and number of diodes connected in series to the device.

FIG. 6 is a graphical representation depicting the electrical characteristics upon application of ESD current between the cathode and the anode of the SDAGGNR device in accordance with the first and second embodiments.

During normal operation of a microchip, the avalanche voltage Vav and the triggering voltage Vtr of the SDAGGNR device are greater than the operation voltage Vop of the microchip. On the other hand, when ESD stress is generated in the microchip, the triggering voltage Vtr of the SDAGGNR device is substantially similar to the core circuit breakdown voltage Vccb of a core circuit in the SDAGGNR device or is greater than the core circuit breakdown voltage of the core circuit due to influence of the added diode. Thus, the SDAGGNR device has difficulty in ensuring fundamental prevention of the ESD current induced into the microchip from flowing to the core circuit to cause breakdown of the core circuit.

On the other hand, the snapback holding voltage Vh of the SDAGGNR device is sufficiently greater than the operation voltage Vop of the microchip. Therefore, during the normal operation of the microchip, there is no problem relating to the latch-up phenomenon due to the SDAGGNR device. The thermal breakdown voltage Vtb of the SDAGGNR device is substantially similar to the triggering voltage Vtr thereof. Thus, when the SDAGGNR device adopts the multi-finger structure, the respective fingers of the SDAGGNR device perform relatively uniform operation. Generally, the SDAGGNR device has a very high current immunity level per unit size of the SDAGGNR device. Generally, the SDAGGNR device can process about 7˜10 times more electrostatic discharge current than a GGNMOS device with the same layout area as that of the SDAGGNR device.

Conclusively, the SDAGGNR device formed by adding a diode to the cathode of the LVTNR device can overcome the latch-up problem of the existing LVTNR device and the non-linear current immunity level of the multi-finger structure. That is to say, it is possible to properly adjust the snap-back holding voltage and thermal breakdown voltage by properly adjusting the size and the number of diodes connected in series to the LVTNR device.

On the hand, the SDAGGNR device has a limit due to insufficient protection of the core circuit of the microchip. To surmount such a limit, a serial diode added gate coupled N-type rectifier (SDAGCNR) device is proposed by coupling a gate in the MOSFET structure of the SDANR device.

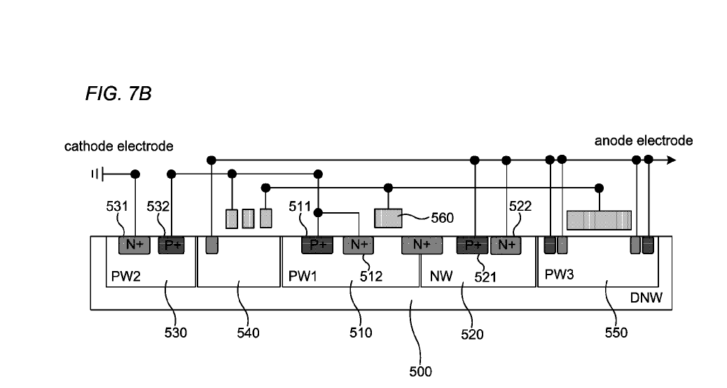

FIGS. 7Aa and 7B are a circuit diagram and a sectional view of an electrostatic discharge protection device in accordance with a third embodiment of the invention.

In the ESD protection device of this embodiment, a P well (PW) 550 for a capacitor is disposed near the N well for the anode at the right side of the SDAGGNR device shown in FIG. 4B. In the SDAGCNR device, a gate of the corresponding SDANR device is connected to the anode via the capacitor and is connected to a cathode or serial diode via a resistor. As the capacitor for connecting the gate to the anode, an N-type MOSFET device may be used, and as the resistor for connecting the gate to the cathode or the serial diode, a poly-silicon resistor may be used.

Referring to FIG. 7B, the ESD protection device of this embodiment includes a P well (PW2) 530 for a diode disposed near a P well (PW1) 510 for a MOSFET and a P well (PW3) 550 for a capacitor disposed at a side of an anode N well (NW) 520 in the LVTNR device which includes the P well (PW1) 510 for forming the MOSFET and the anode N well (NW) 520 in a deep-N well (DNW) 500. An N well 540 is interposed between the P wells 510, 530 to separate the P wells 510, 530 from each other. An N⁺ region 531 for internal diffusion of the diode and a P⁺ region 532 for diode pick-up are disposed in the P well (PW) 530 for forming the diode. The N⁺ region 531 becomes a cathode, and an anode P⁺ region 521 and an anode N⁺ region 522 of the LVTNR device are combined to constitute an anode.

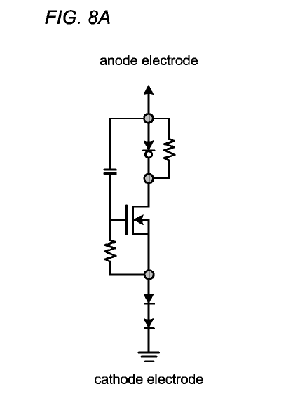

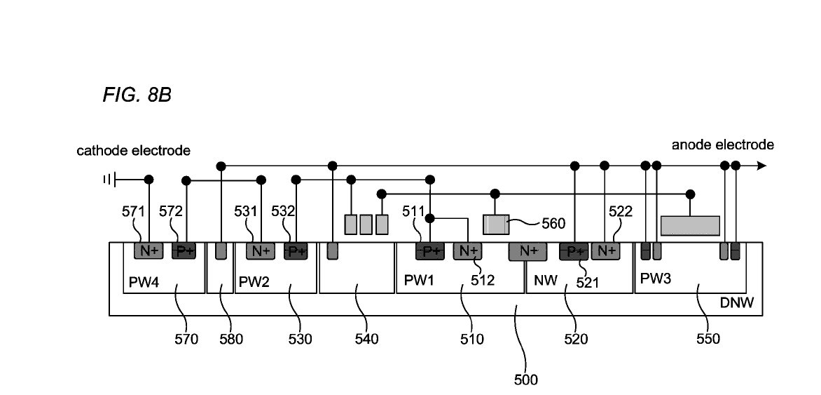

FIGS. 8A and 8B are a circuit diagram and a sectional view of an electrostatic discharge protection device in accordance with a fourth embodiment of the invention.

The ESD protection device of this embodiment includes an additional serial diode connected to the left side of the serial diode of the device shown in FIG. 7B. In other words, a P well (PW4) 570 for a second diode is disposed at the left side of the P well (PW2) for a first diode and is separated therefrom by an N well 580. An N⁺ region 571 for internal diffusion of the diode and a P⁺ region 572 for diode pick-up are disposed inside the P well (PW) 570 for the second diode. The inner N⁺ region 571 becomes a cathode, and an anode P⁺ region 521 and an anode N⁺ region 522 of the LVTNR device are combined to constitute an anode.

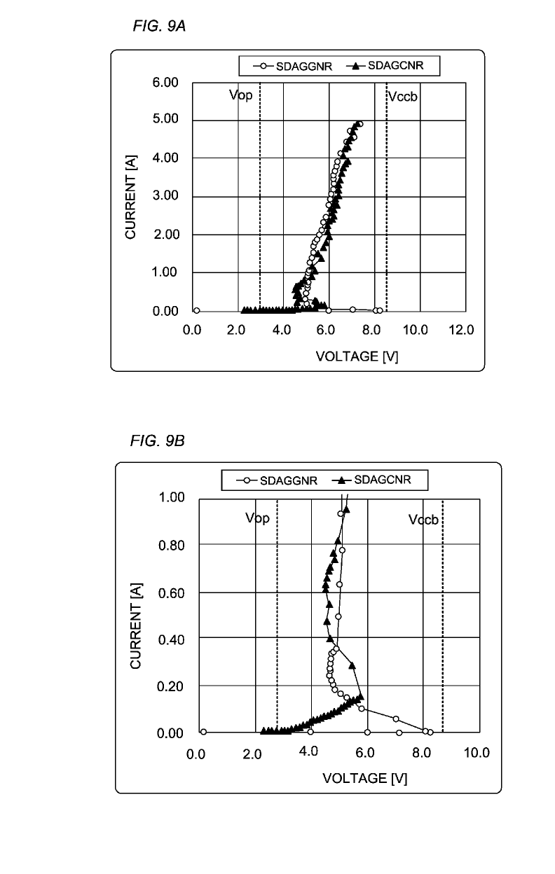

FIGS. 9A and 9B are graphical representations depicting electrical characteristics upon application of electrostatic discharge current between the cathode and the anode of the SDAGCNR device according to the fourth and fifth embodiments.

Capacitance of the capacitor and resistance of the resistor for coupling the gate in the SDAGCNR device determine the duration for which coupling of the gate lasts. Thus, it is possible to allow the SDAGCNR device to operate like the SDAGGNR device during normal operation of the microchip by adjusting the capacitance of the capacitor and the resistance of the resistor which are used for coupling the gate. This means that the avalanche voltage Vav and the triggering voltage Vtr of the SDAGCNR device may be adjusted to become the same as those of the SDAGGNR device during the normal operation of the microchip by properly adjusting the capacitance of the capacitor and the resistance of the resistor which are used for coupling the gate. Therefore, the avalanche voltage and the triggering voltage of the SDAGCNR device may be adjusted to become higher than the operation voltage Vop of the microchip during the normal operation thereof.

When electrostatic discharge stress is generated in the microchip, the triggering voltage Vtr of the SDAGCNR device is sufficiently lower than the core circuit breakdown voltage Vccb of the microchip device. Thus, it is possible to ensure fundamental prevention of the ESD current induced into the microchip from flowing to the core circuit to cause breakdown of the core circuit.

Further, the snapback holding voltage Vh of the SDAGCNR device is sufficiently greater than the operation voltage Vop of the microchip. Therefore, during the normal operation of the microchip, there is no problem relating to the latch-up phenomenon due to the SDAGCNR device. Additionally, the thermal breakdown voltage Vtb of the SDAGCNR device is sufficiently greater than the triggering voltage Vtr thereof. Thus, when the SDAGCNR device adopts the multi-finger structure, the respective fingers of the SDAGCNR device perform relatively uniform operation. Moreover, the SDAGCNR device has a very high current immunity level per unit size of the SDAGCNR device.

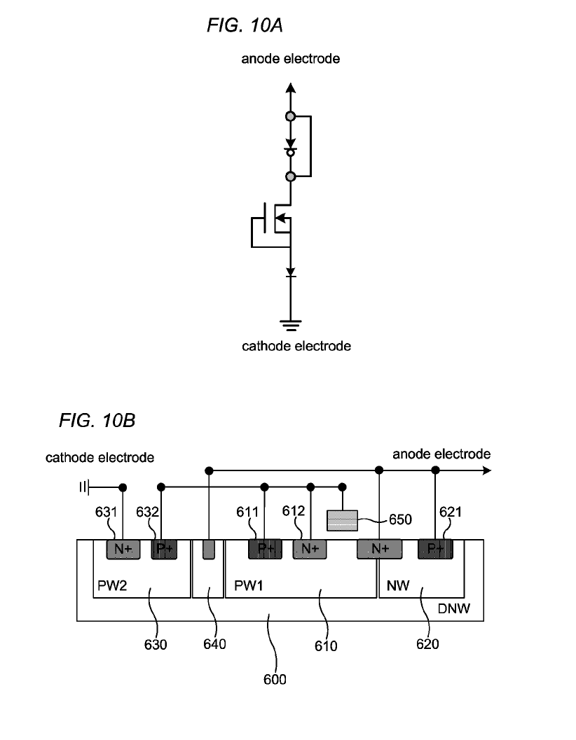

FIGS. 10A and 10B are a circuit diagram and a sectional view of an electrostatic discharge protection device in accordance with a fifth embodiment of the invention.

In the ESD protection device of this embodiment, a drain N⁺ region 621 is directly connected to an anode instead of forming an anode N⁺ region in formation of the LVTNR device. Specifically, in the electrostatic discharge protection device of this embodiment, a P well (PW2) 630 for a diode is disposed near a P well (PW1) 610 for a MOSFET in the LVTNR device which includes the P well (PW1) 610 for forming the MOSFET and an anode N well (NW) 620 in a deep-N well (DNW) 600 formed in a predetermined region of a semiconductor substrate (not shown). An N well (NW) 640 is interposed between the two P wells 610, 630 to separate the P wells 610, 630 from each other. An N⁺ region 631 for internal diffusion of the diode and a P⁺ region 632 for diode pick-up are disposed in the P well (PW2) 630 for forming the diode. A cathode P⁺ region 611 and a cathode N⁺ region 612 are connected to a gate 650 and extend to be connected to the P⁺ region 632 for diode pick-up, and the N⁺ region 631 finally becomes a cathode. The drain N⁺ region 621 is directly connected to the anode.

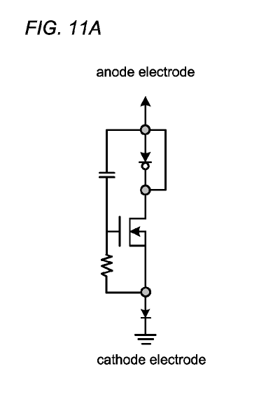

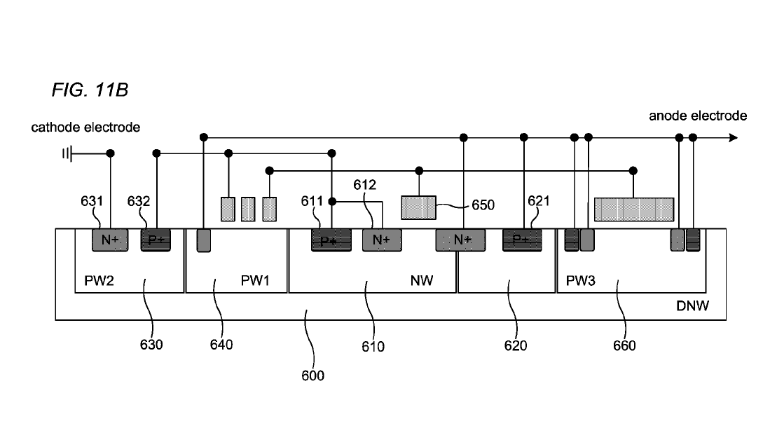

FIGS. 11A and 11B are a circuit diagram and a sectional view of an ESD protection device, which further includes a P well (PW3) 660 for a capacitor disposed at a side of the anode N well (NW) in the ESD protection device shown in FIGS. 10A and 10B.

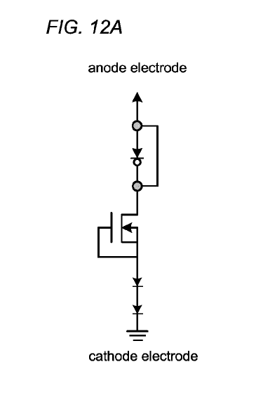

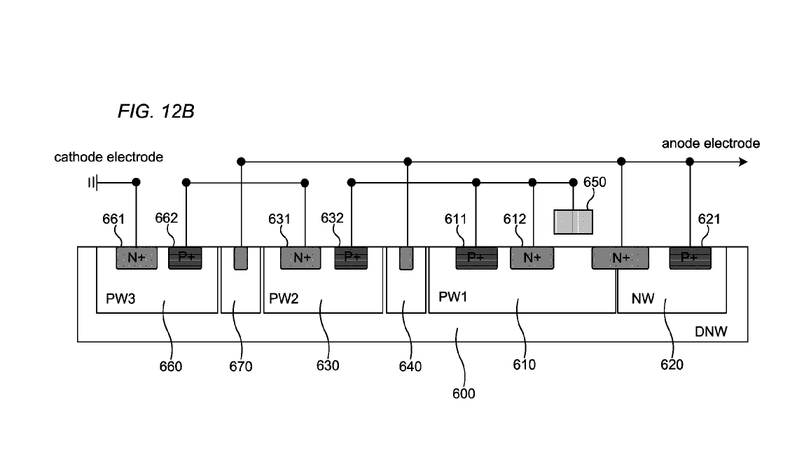

FIGS. 12A and 12B are a circuit diagram and a sectional view of an ESD protection device, wherein the two diodes of the ESD protection device shown in FIGS. 10A and 10B are disposed in series. That is, the ESD protection device of this embodiment further includes a P well (PW3) 660 disposed at a side of the P well (PW2) 630 for the diode and an N well (NW) 670 is disposed to separate the P wells 630, 660 from each other. An N⁺ region 661 of the diode disposed at the outermost region is connected to a cathode.

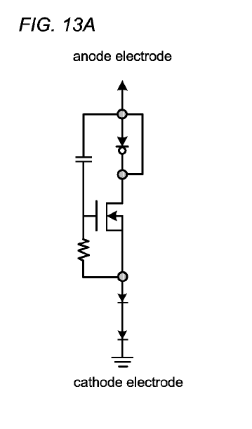

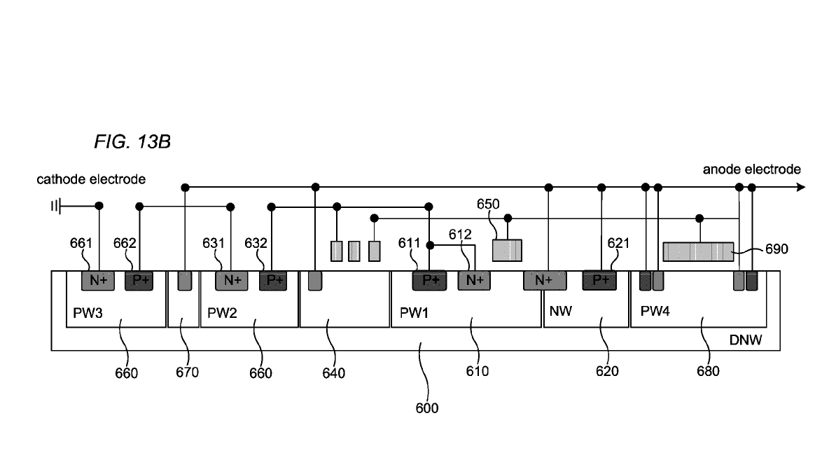

FIGS. 13A and 13B are a circuit diagram and a sectional view of an ESD protection device, which further includes a P well (PW3) 680 for a capacitor disposed at a side of the anode N well (NW) 620 in the ESD protection device shown in FIGS. 12A and 12B.

Each of the devices shown in FIGS. 11A to 13B still has a rectifier structure between the anode and the cathode by coupling the LNPN bipolar transistor and the VPNP bipolar transistor. Thus, the method of developing the corresponding SDANR structure based on the LVTNR device of this structure and the gate coupling manner are the same as in the embodiments described above.

The modified devices exhibit the same effects in terms of electrical characteristics except for a slight reduction of operation status resistance of the LNPN bipolar transistor. In other words, the devices of these embodiments also exhibit similar electrical characteristics to those of the SDANR device.

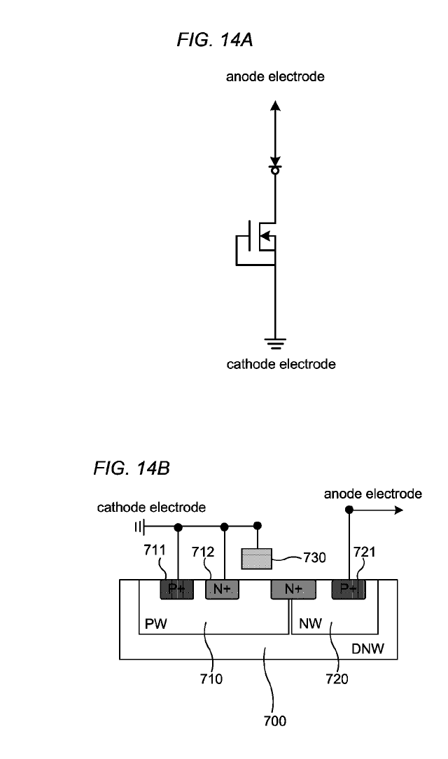

FIGS. 14A and 14B are a circuit diagram and a sectional view of an electrostatic discharge protection device in accordance with yet another embodiment of the invention.

In this embodiment, an anode may be formed only using an anode P⁺ diffusion region without an anode N⁺ diffusion region in formation of the existing LVTNR device. In other words, a P well (PW) 710 for a MOSFET and an anode N well (NW) 720 are disposed in a deep-N well (DNW) 700 formed in a predetermined region of a semiconductor substrate (not shown). A P⁺ region 711 and an N⁺ region 712 of the MOSFET are combined with a gate 730 and connected to a cathode, and an anode P⁺ region 721 is connected to an anode.

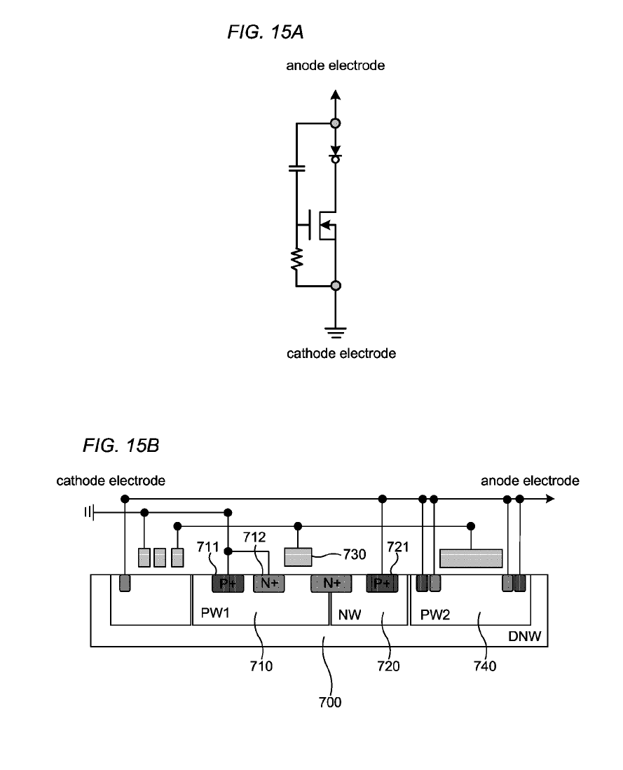

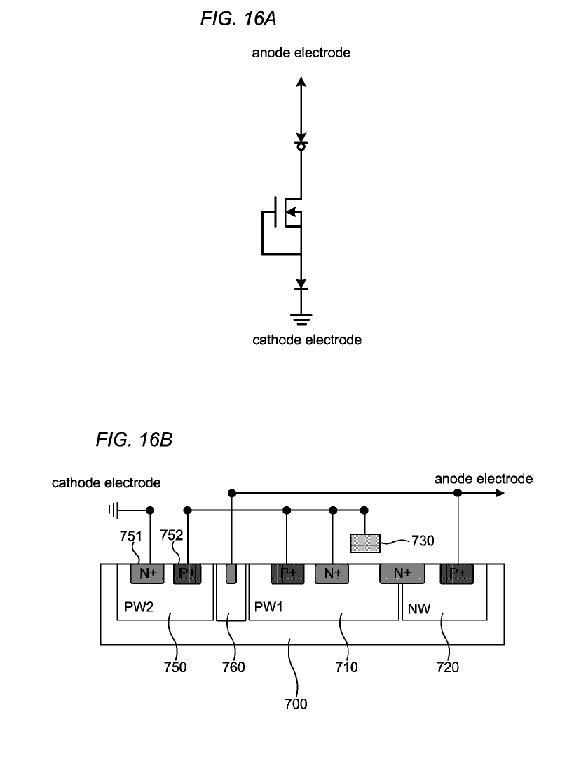

FIGS. 15A and 15B show an ESD protection device which further includes a P well (PW2) 740 for a capacitor disposed at a side of the anode P well in the device of FIGS. 14B and 14B. FIGS. 16A and 16B show an ESD protection device which includes a diode connected in series to a side of the MOSFET region. In the device of this embodiment, a P well (PW2) 750 for a diode is disposed at a side of a P well (PW1) 710 for the MOSFET, and an N⁺ region 751 and a P⁺ region 752 for diode pick-up are disposed in the P well 750 for the diode.

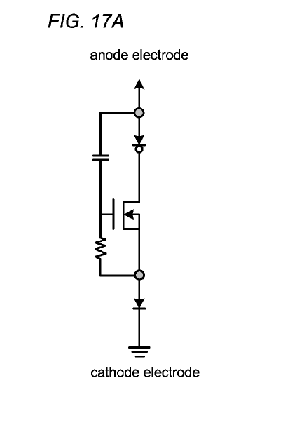

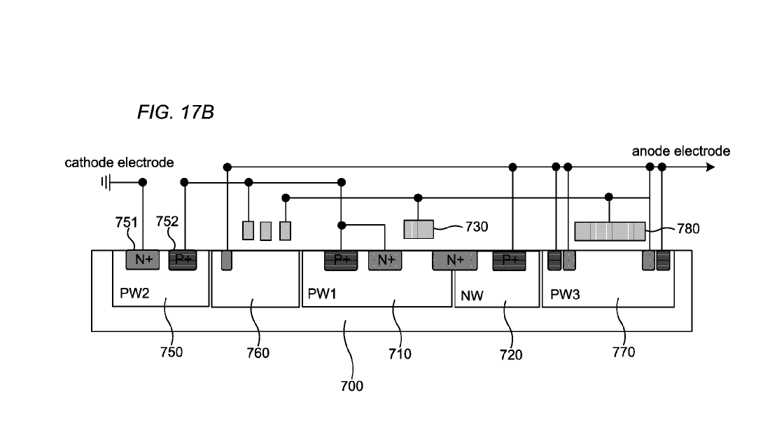

FIGS. 17A and 17B show an ESD protection device which further includes a P well (PW3) 770 for a capacitor at a side of the anode P well 720 in the device of FIGS. 16A and 16B.

Referring to FIGS. 14A to 17B, each of the devices still has a rectifier structure formed between the anode and the cathode by coupling the LNPN bipolar transistor and the VPNP bipolar transistor. In view of the LNPN bipolar transistor, however, the P⁺ region/NW diode is added in series to the LNPN bipolar transistor.

In view of the overall rectifier structure, the structures of FIGS. 14A to 17B seem to have an additional single serial diode between the anode and the cathode. Accordingly, the method of developing the SDANR structure based on the LVTNR device is carried out by reducing the number of P⁺ region/NW diodes to be added to the cathode by one.

These modified devices exhibit the same electrical characteristics except that during operation of the LNPN bipolar transistor, the avalanche voltage and the triggering voltage of the LNPN bipolar transistor increase corresponding to an increase in avalanche voltage and triggering voltage of the diode for forward operation. Generally, during the forward operation of the diode, both the avalanche voltage and the triggering voltage of the diode are very low values of 0.6 V or less, which can be considered negligible in an electrostatic discharge circumstance. Thus, the electrical characteristics of the devices shown in FIGS. 14A to 17B can be considered the same as the electrical characteristics of the SDANR device under electrostatic discharge stress.

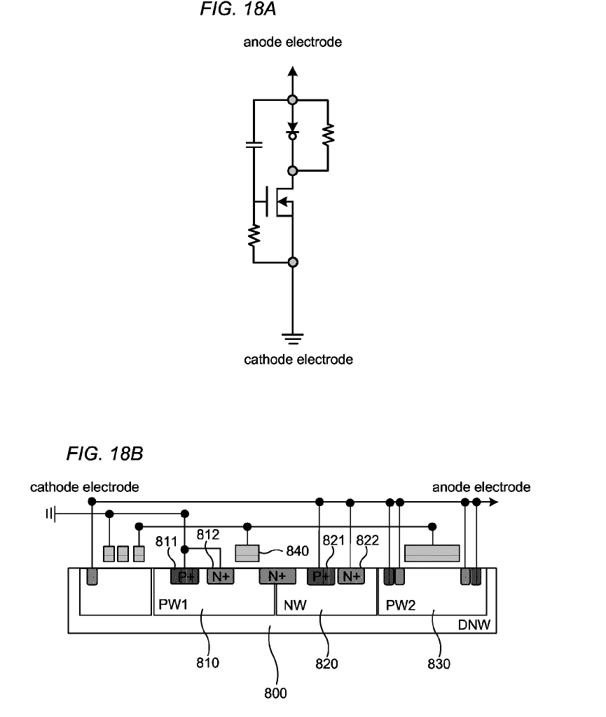

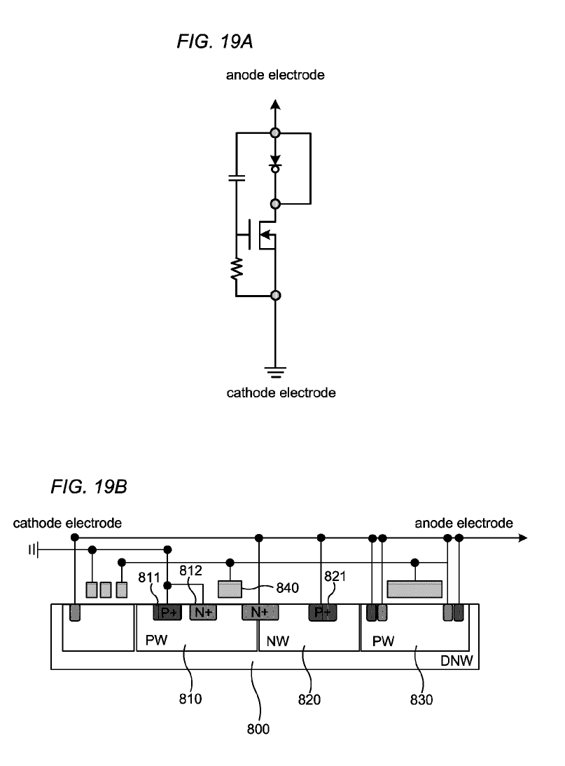

FIGS. 18A to 19B are circuit diagrams and sectional views of ESD protection devices in accordance with other embodiments of the invention.

The devices of these embodiments are low voltage triggering gate coupled N-type rectifier (LVTCNR) electrostatic discharge protection devices, each of which is formed by coupling a gate in the MOSFET structure of the LVTNR device.

In each of the devices of these embodiments, a P well (PW2) 830 for a capacitor is disposed near an anode N well 820 in the LVTNR device which includes a P well (PW1) 810 for forming the MOSFET and the anode N well (NW) 820 in a deep N well (DNW) 800 formed in a predetermined region of a semiconductor substrate (not shown). A cathode P⁺ region 811 and a cathode N⁺ region 812 are connected to a cathode, and a gate electrode 840 of the MOSFET is connected to an anode via the capacitor to which the gate electrode 840 is coupled.

When ESD stress is generated in a microchip, the triggering voltage of the LVTGCNR device is lower than that of the existing LVTNR device. Thus, it is possible for LVTGCNR device to ensure fundamental prevention of the ESD current induced into the microchip from flowing to a core circuit of the microchip to cause breakdown.

Although some embodiments have been provided to illustrate the invention in conjunction with the drawings, it will be apparent to those skilled in the art that the embodiments are given by way of illustration only, and that that various modifications, changes, alterations, and equivalent embodiments can be made without departing from the spirit and scope of the invention. The scope of the invention should be limited only by the accompanying claims.

In addition, in describing the invention, even though the cathode (or anode) is used together with the cathode electrode (or anode electrode), they have the same meaning.

What is claimed is:

1. An electrostatic discharge (ESD) protection device comprising:
a diode comprising N well/P⁺ diffusion regions;
a resistor connected in parallel to the diode;
a MOS transistor having a drain connected to the diode and the resistor and constituting a cathode along with a source and a gate; and
at least one diode connected in series to the cathode.

2. The ESD protection device according to claim 1, wherein the ESD protection device comprises:
a deep-N well region formed in a predetermined region on a semiconductor substrate, and
a P well region and an N well region formed adjacent to each other in the deep-N well region, the MOS transistor being formed in the P well region and the resistor comprising an impurity region formed in the N well region.

3. The ESD protection device according to claim 1, wherein the diode connected to the cathode comprises:
a P well region for the diode formed a predetermined distance from a well region where the MOS transistor is disposed, and
an inner N⁺ impurity region and a P⁺ impurity region for diode pick-up formed in the P well region for the diode.

4. The ESD protection device according to claim 3, wherein the P well region for the diode is electrically separated from the MOS transistor by an N-type well disposed between the P well region for the diode and the well region where the MOS transistor is disposed.

5. The ESD protection device according to claim 3, wherein the inner N⁺ impurity region for the diode is connected to the cathode.

6. The ESD protection device according to claim 1, further comprising:
a capacitor connected between an anode of the diode and the gate of the MOS transistor; and
a resistor connected between the anode of the diode connected to the cathode and the gate of the MOS transistor.

7. An ESD protection device comprising:
a diode comprising N well/P⁺ diffusion regions;
a MOS transistor having a drain connected to the diode and constituting a cathode along with a source and a gate; and
at least one diode connected in series to the cathode.

8. The ESD protection device according to claim 7, wherein the ESD protection device comprises:
a deep-N well region formed in a predetermined region on a semiconductor substrate; and
a P well region and an N well region formed adjacent to each other in the deep-N well region, the MOS transistor being formed in the P well region.

9. The ESD protection device according to claim 7, wherein the diode connected to the cathode comprises:
a P well region for the diode formed a predetermined distance from a well region where the MOS transistor is disposed, and
an inner N⁺ impurity region and a P⁺ impurity region for diode pick-up formed in the P well region for the diode.

10. The ESD protection device according to claim 9, wherein the P well region for the diode is electrically separated from the MOS transistor by an N-type well disposed between the P well region for the diode and the P well region where the MOS transistor is disposed.

11. The ESD protection device according to claim 9, wherein the inner N+ impurity region for the diode is connected to the cathode.

12. The ESD protection device according to claim 7, further comprising:
a capacitor connected between an anode of the diode and the gate of the MOS transistor; and
a resistor connected between the anode of the diode connected to the cathode and the gate of the MOS transistor.

13. An ESD protection device comprising:
a semiconductor substrate;
a deep-N well region formed in a predetermined region on the semiconductor substrate;
a P well region and an N well region formed adjacent to each other in the deep-N well region;
a MOS transistor formed in the P well region; and
an anode P⁺ impurity region formed in the N well region, the anode P⁺ impurity region being connected to an anode.

14. The ESD protection device according to claim 13, further comprising:
a P well region for a capacitor disposed adjacent to the N well region where the anode P⁺ impurity region is disposed, the capacitor being coupled to a gate of the MOS transistor.

15. The ESD protection device according to claim 13, further comprising:
at least one diode connected in series to a cathode of the MOS transistor.

16. The ESD protection device according to claim 14, further comprising:
at least one diode connected in series to a cathode of the MOS transistor.
